(19) United States
(12) Patent Application Publication
(10) Pub. No.: US 2023/0136141 A1
(43) Pub. Date: May 4, 2023

(54) METHOD AND APPARATUS FOR CONTROLLING DISTRIBUTION SEQUENCE FOR SEMICONDUCTOR DEVICE, AND STORAGE MEDIUM

(71) Applicant: CHANGXIN MEMORY TECHNOLOGIES, INC., Hefei City (CN)

(72) Inventors: Chunyang WANG, Hefei City (CN); Zhenxing LI, Hefei City (CN); Yuming WANG, Hefei City (CN); Fang WANG, Hefei City (CN); SAN-CHEN CHEN, Hefei City (CN); CHEN-HUA SHEN, Hefei City (CN)

(73) Assignee: CHANGXIN MEMORY TECHNOLOGIES, INC., Hefei City (CN)

(21) Appl. No.: 17/658,823

(22) Filed: Apr. 11, 2022

(30) Foreign Application Priority Data
Nov. 4, 2021 (CN) 202111302275.7

(51) Int. Cl. G05B 19/4099

(52) U.S. Cl. CPC G05B 19/4099; G05B 2219/45031

(57) ABSTRACT

A method a for controlling a distribution sequence for a semiconductor device includes: acquiring the quantity of all chambers and an actual working duration of each radio frequency device in the machines; providing an optimal working duration of the radio frequency device to calculate an average interval; sorting all the data to form a first queue data set, and obtaining a difference between adjacent data in the first queue data set; using a difference between adjacent consecutive data as a feature value corresponding to the former or latter data in the consecutive data, and using data that does not correspond to the difference as a feature value corresponding to the data; obtaining a second queue data set and a third queue data set; and obtaining a distribution sequence of distributing N batches of wafers to all the radio frequency devices.

### CROSS-REFERENCE TO RELATED APPLICATION

This application claims priority to Chinese Patent Application No. 202111302275.7 filed on Nov. 4, 2021, the disclosure of which is hereby incorporated by reference in its entirety.

### BACKGROUND

It is vital to monitor and control processing parameters during the manufacturing of semiconductor structures to obtain high-quality semiconductor structures. A semiconductor device for manufacturing a semiconductor structure usually includes a chamber and a radio frequency device located in the chamber. For the radio frequency device, even if input parameters are constant, the electrical performance of the radio frequency device gradually degrades as an actual operating duration of the radio frequency device increases, which affects the production capacity of the semiconductor device. Therefore, there is usually an upper limit for the actual operating duration of the radio frequency device, and the radio frequency device requires maintenance when the actual operating duration of the radio frequency device reaches the upper limit.

### SUMMARY

Embodiments of the disclosure relate to the field of semiconductors, and provide a method and an apparatus for controlling a distribution sequence for a semiconductor device, which at least helps to improve the stability of the production capacity of a semiconductor device.

According to some embodiments of the disclosure, an aspect of the embodiments of the disclosure provides a method for controlling a distribution sequence for a semiconductor device. The semiconductor device may include a plurality of machines. Each machine has at least one chamber and a radio frequency device in a one-to-one correspondence with the chamber. The method may include: before preset process processing is performed on N batches of wafers, acquiring the quantity of all chambers in which the preset process processing is allowed and data of all the machines, where the data is an actual working duration of each radio frequency device in the machines; providing optimal working durations of the radio frequency devices, and calculating an average interval according to the optimal working durations and the quantity; sorting all the data to form a first queue data set, and obtaining a difference between adjacent data in the first queue data set; obtaining feature values corresponding to the data in the first queue data set based on the difference, where a difference between adjacent consecutive data is used as a feature value corresponding to the former or latter data in the consecutive data, and data that does not correspond to the difference is used as a feature value corresponding to the data; obtaining a second queue data set and a third queue data set based on the average interval and the feature values, where the second queue data set is formed by sorting data corresponding to feature values less than the average interval, and the third queue data set is formed by sorting data corresponding to feature values greater than or equal to the average interval; and obtaining, based on the second queue data set and the third queue data set, a distribution sequence of distributing the N batches of wafers to all the radio frequency devices to perform the preset process processing.

According to some embodiments of the disclosure, another aspect of the embodiments of the disclosure further provides an apparatus for controlling a distribution sequence for a semiconductor device. The semiconductor device includes a plurality of machines, each machine having at least one chamber and a radio frequency device corresponding one to one to the chamber, and the apparatus may include: a processor; and a memory storing instructions executable by the processor. When executing the instructions stored in the memory, the processor is configured to: before preset process processing is performed on N batches of wafers, acquire a quantity of all chambers in which the preset process processing is allowed and data of all the machines, wherein the data is an actual working duration of each radio frequency device in the machines; provide optimal working durations of the radio frequency devices, and calculate an average interval according to the optimal working durations and the quantity; sort all the data to form a first queue data set, and obtain a difference between adjacent data in the first queue data set; obtain feature values corresponding to the data in the first queue data set based on the difference, wherein a difference between adjacent consecutive data is used as a feature value corresponding to the former or latter data in the consecutive data, and data that does not correspond to the difference is used as a feature value corresponding to the data; obtain a second queue data set and a third queue data set based on the average interval and the feature values, wherein the second queue data set is formed by sorting data corresponding to feature values less than the average interval, and the third queue data set is formed by sorting data corresponding to feature values greater than or equal to the average interval; and obtain, based on the second queue data set and the third queue data set, a distribution sequence of distributing the N batches of wafers to all the radio frequency devices to perform the preset process processing.

According to some embodiments of the disclosure, still another aspect of the embodiments of the disclosure further provides a non-volatile computer-readable storage medium, which has computer program stored thereon. When executed by an electronic device, the computer program causes a processor in the electronic device to implement the method for controlling a distribution sequence for a semiconductor device as described in the embodiments of the disclosure.

### BRIEF DESCRIPTION OF THE DRAWINGS

One or more embodiments are exemplarily described by using a diagram that corresponds to the one or more embodiments in the accompanying drawings. These exemplary descriptions do not constitute a limitation to the embodiments. Elements with the same reference numeral in the accompanying drawings are denoted as similar elements. Unless specifically indicated, the diagrams in the accompanying drawings do not constitute any limitations on proportions.

FIG. 1 is a flowchart of a method for controlling a distribution sequence for a semiconductor device according to an embodiment of the disclosure;

FIG. 2 is another flowchart of a method for controlling a distribution sequence for a semiconductor device according to an embodiment of the disclosure;

FIG. 3 is still another flowchart of a method for controlling a distribution sequence for a semiconductor device according to an embodiment of the disclosure; and

FIG. 4 is a schematic diagram of functional modules of an apparatus for controlling a distribution sequence for a semiconductor device according to another embodiment of the disclosure.

### DETAILED DESCRIPTION

A plurality of machines is usually included to manufacture a semiconductor structure, and radio frequency devices are used in most of the machines. To prevent all actual operating durations of a plurality of radio frequency devices from reaching upper limits at the same time to avoid causing serious instantaneous loss of production capacity and avoid affecting the stability of the production capacity of a semiconductor device, there is an urgent need for a method for intelligently controlling actual operating durations of a plurality of radio frequency devices to improve the stability of the production capacity of the semiconductor device.

Various embodiments of the present disclosure can improve the stability of the production capacity of semiconductor devices.

It is found through analysis that a plurality of machines are usually included to manufacture a semiconductor structure, and radio frequency devices are used in most of the machines. Changes in the electrical performance of the radio frequency devices indirectly cause changes in the temperature of a chamber or a semiconductor structure, which affects the quality of formed semiconductor structures. In addition, the electrical performance of a radio frequency device gradually degrades as an actual operating duration of the radio frequency device increases. There is usually an upper limit for the actual operating duration of the radio frequency device, and the radio frequency device requires maintenance when the actual operating duration of the radio frequency device reaches the upper limit. Therefore, it is necessary to collect or monitor related parameters of radio frequency devices. For example, actual working durations of radio frequency devices are collected, to determine whether the electrical performance of the radio frequency devices is stable, to determine which radio frequency devices are to be put into production and which radio frequency devices are to be maintained.

However, at present, related data is usually manually collected or monitored, and it is manually determined which radio frequency devices are to be put into production and which radio frequency devices are to be maintained, which is time and labor consuming. Therefore, there is an urgent need for a method and an apparatus for controlling a distribution sequence for a semiconductor device, to intelligently control which radio frequency devices are to participate in work and improve the stability of the production capacity of a semiconductor device.

Embodiments of the disclosure provide a method and an apparatus for controlling a distribution sequence for a semiconductor device. In the method, most radio frequency devices with relatively short actual working durations are categorized in a second queue data set, and the radio frequency devices in the second queue data set may be preferentially arranged to perform preset process processing on N batches of wafers, so that excessive radio frequency devices with actual working durations approaching optimal working durations are prevented from participating in work, to avoid affecting the quality of semiconductor structures and reduce the production capacity of a semiconductor device. In addition, when the quantity of batches of wafers that require preset process processing is not large, radio frequency devices corresponding to data in a third queue data set may be arranged for maintenance, thereby preventing all actual operating durations of a plurality of radio frequency devices from reaching upper limits at the same time, to avoid serious instantaneous loss of production capacity, thereby helping to improve the stability of the production capacity of the semiconductor device.

The embodiments of the disclosure are described below in detail with reference to the accompanying drawings. However, a person of ordinary skill in the art may understand that in the embodiments of the disclosure, many technical details are provided for a reader to better understand the embodiments of the disclosure. However, even in the absence of these technical details and various changes and modifications based on the following embodiments, the embodiments of the disclosure can be implemented.

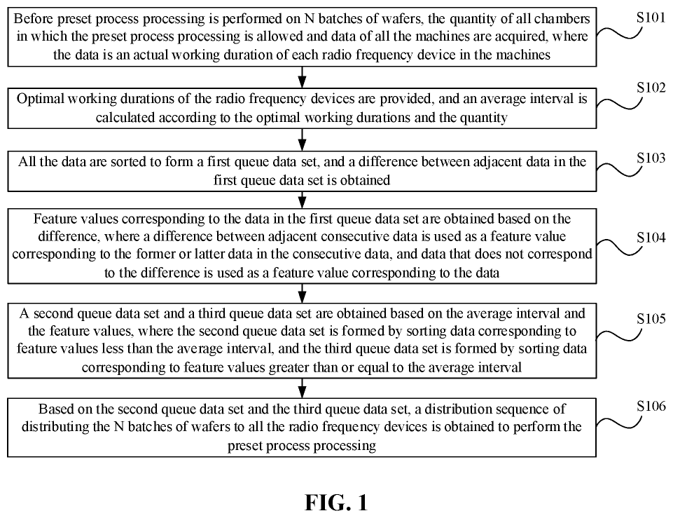

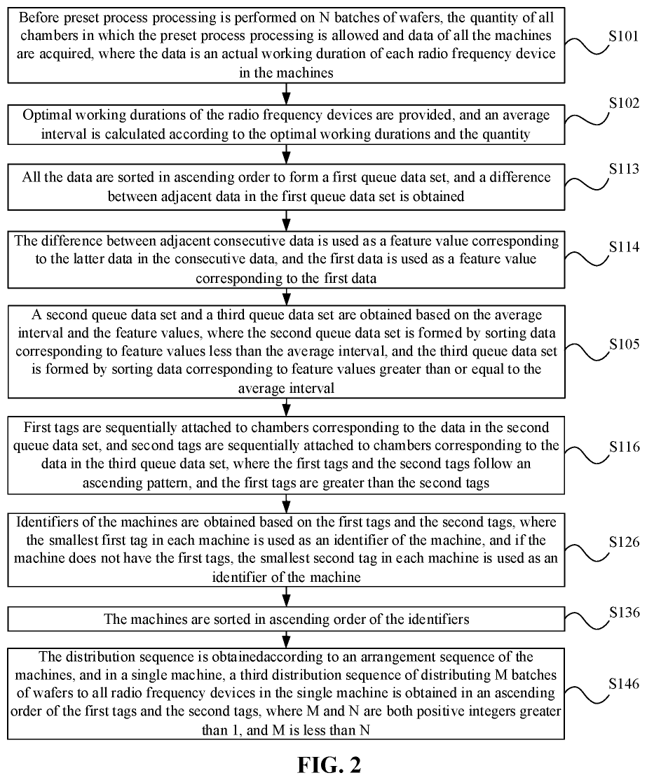

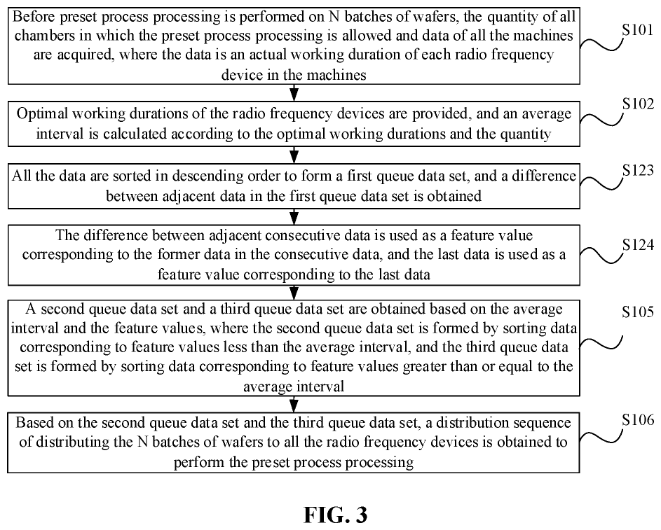

An embodiment of the disclosure provides a method for controlling a distribution sequence for a semiconductor device. A semiconductor structure provided in the embodiment of the disclosure is described below in detail with reference to the accompanying drawings. FIG. 1 is a flowchart of a method for controlling a distribution sequence for a semiconductor device according to an embodiment of the disclosure. FIG. 2 is another flowchart of a method for controlling a distribution sequence for a semiconductor device according to an embodiment of the disclosure. FIG. 3 is still another flowchart of a method for controlling a distribution sequence for a semiconductor device according to an embodiment of the disclosure.

FIG. 1 to FIG. 3 show a method for controlling a distribution sequence for a semiconductor device. The semiconductor device includes a plurality of machines. Each machine has at least one chamber and a radio frequency device in a one-to-one correspondence with the chamber. It needs to be noted that the radio frequency device is located in the radio frequency device. One chamber corresponds to one radio frequency device. For some machines, there is only one chamber. However, in some machines, there may be a plurality of chambers and a plurality of radio frequency devices corresponding to the chambers.

Referring to FIG. 1 to FIG. 3, the method for controlling a distribution sequence for a semiconductor device includes the following steps.

In S101, before preset process processing is performed on N batches of wafers, the quantity of all chambers in which the preset process processing is allowed and data of all the machines are acquired, where the data is an actual working duration of each radio frequency device in the machines.

It needs to be noted that because the data corresponds one to one to the radio frequency devices and the radio frequency devices correspond one to one to the chambers, the data and the chambers also have a one-to-one correspondence relationship. That is, an actual working duration of one radio frequency device corresponds to one chamber. Subsequently, based on different data, different tags are attached to chambers corresponding to different data.

In S102, optimal working durations of the radio frequency devices are provided, and an average interval is calculated according to the optimal working durations and the quantity.

It needs to be noted that an optimal working duration of a radio frequency device is an upper limit of an actual working duration of the radio frequency device. When the actual working duration of the radio frequency device is greater than the optimal working duration, the electrical performance of the radio frequency device degrades, and other processing parameters in the chamber decrease. For example, when the chamber corresponding to the radio frequency device is used for plasma processing, if the actual working duration of the radio frequency device is greater than the optimal working duration, both the density of plasma and the uniformity of plasma decrease, which affects the quality and efficiency of eventually formed semiconductor structures, reduces the yield of semiconductor structures, and reduces the production capacity of a semiconductor device.

The average interval is a ratio of the optimal working duration to the quantity of chambers in which the preset process processing is allowed. For example, the optimal working duration of the radio frequency device is 300 hours, and the quantity of all chambers in which the preset process processing is allowed is 6. In this case, the average interval may be 50 hours.

In this step, the optimal working duration of the radio frequency device is provided, and the average interval is obtained, to facilitate subsequent grouping of a plurality of radio frequency devices by using the average interval, so that a group in which actual working durations of most radio frequency devices are relatively short is formed, that is, a corresponding second queue data set formed subsequently. In this way, subsequently the radio frequency devices corresponding to the data in the second queue data set may be mainly used to manufacture semiconductor structures, so that excessive radio frequency devices with actual working durations approaching optimal working durations are prevented from participating in work, to avoid affecting the quality of semiconductor structures and reduce the production capacity of a semiconductor device.

In S103, all the data is sorted to form a first queue data set, and a difference between adjacent data in the first queue data set is obtained.

All data is sorted, so that data is arranged in gradually ascending order or in gradually descending order, and it is impossible that one of two adjacent pieces of data is data that approximates a maximum value in the first queue data set and the other is data that approximates a minimum value in the first queue data set, to avoid an extremely large value difference between two adjacent differences, thereby improving the subsequent value of data analysis and classification.

In S104, feature values corresponding to the data in the first queue data set are obtained based on the difference, where a difference between adjacent consecutive data is used as a feature value corresponding to the former or latter data in the consecutive data, and data that does not correspond to the difference is used as a feature value corresponding to the data.

In some embodiments, the following two manners may be used to sort all the data and obtain the feature value corresponding to the data in the first queue data set based on the difference:

In some embodiments, referring to FIG. 2, the step of sorting all the data and obtaining a feature value corresponding to the data in the first queue data set based on the difference includes the following steps.

In S113, all the data is sorted in ascending order to form a first queue data set, and a difference between adjacent data in the first queue data set is obtained.

In S114, the difference between adjacent consecutive data is used as a feature value corresponding to the latter data in the consecutive data, and first data is used as a feature value corresponding to the first data.

For example, the first queue data set may be {5, 37, 80, 87, 225, 285}. A feature value corresponding to 5 is 5. A feature value corresponding to 37 is a difference of 32 between 37 and 5. A feature value corresponding to 80 is a difference of 43 between 80 and 37. A feature value corresponding to 225 is a difference of 138 between 225 and 80. A feature value corresponding to 285 is a difference of 60 between 285 and 225.

Because all the data is sorted in ascending order, actual working durations of a plurality of radio frequency devices are arranged in gradually ascending order. An actual working duration of a radio frequency device corresponding to first data in the first queue data set is the smallest, and a value of the data is used as the feature value, to facilitate subsequent categorization of the data into the second queue data set. In addition, an actual working duration of a radio frequency device corresponding to data near the bottom in the first queue data set is closer to the optimal working duration. When a feature value is assigned to the latter data in the adjacent consecutive data, if it is determined subsequently that the feature value is greater than the average interval, categorization of data with a larger value in the adjacent consecutive data into a third queue data set is facilitated, that is, a probability that a radio frequency device with a relatively long actual working duration in the radio frequency devices is categorized into the third queue data set is increased.

In some other embodiments, referring to FIG. 3, the step of sorting all the data and obtaining a feature value corresponding to the data in the first queue data set based on the difference includes the following steps.

In S123, all the data is sorted in descending order to form a first queue data set, and a difference between adjacent data in the first queue data set is obtained.

In S124, the difference between adjacent consecutive data is used as a feature value corresponding to the former data in the consecutive data, and last data is used as a feature value corresponding to the last data.

For example, the first queue data set may be {285, 225, 87, 80, 37, 5}. A feature value corresponding to 285 is a difference of 60 between 285 and 225. A feature value corresponding to 225 is a difference of 138 between 225 and 80. A feature value corresponding to 80 is a difference of 43 between 80 and 37. A feature value corresponding to 37 is a difference of 32 between 37 and 5. A feature value corresponding to 5 is 5.

Because all the data is sorted in descending order, actual working durations of a plurality of radio frequency devices are arranged in gradually descending order. An actual working duration of a radio frequency device corresponding to last data in the first queue data set is the smallest, and a value of the data is used as the feature value, to facilitate subsequent categorization of the data into the second queue data set. In addition, an actual working duration of a radio frequency device corresponding to data near the top in the first queue data set is closer to the optimal working duration. When a feature value is assigned to the former data in the adjacent consecutive data, if it is determined subsequently that the feature value is greater than the average interval, categorization of data with a larger value in the adjacent consecutive data into the third queue data set is facilitated, that is, a probability that a radio frequency device with a relatively long actual working duration in the radio frequency devices is categorized into the third queue data set is increased.

With continued reference to FIG. 1, in S105, a second queue data set and a third queue data set are obtained based on the average interval and the feature values, where the second queue data set is formed by sorting data corresponding to feature values less than the average interval, and the third queue data set is formed by sorting data corresponding to feature values greater than or equal to the average interval.

In some embodiments, the step of forming the second queue data set and the third queue data set through sorting includes: sorting the data of the feature values less than the average interval in ascending order of the feature values to form the second queue data set; and sorting the data of the feature values greater than or equal to the average interval in ascending order of the feature values to form the third queue data set.

Because a feature value of data in the second queue data set is less than the average interval and a feature value of data in the third queue data set is greater than or equal to the average interval, a probability that actual working durations of radio frequency devices in the first chambers are relatively short is greater than a probability that actual working durations of radio frequency devices in the second chambers are relatively short, so that subsequently it is convenient to preferentially arrange chambers corresponding to the data in the second queue data set to perform wafer processing work.

For example, the average interval is 50 hours, and the first queue data set is {5, 37, 80, 87, 225, 285}. On this basis, because feature values 5, 32, 43, and 7 that correspond to 5, 37, 80, and 87 respectively are all less than the average interval of 50 hours, the second queue data set is {5, 37, 80, 87}. Because feature values 138 and 60 that correspond to 225 and 285 respectively are both greater than the average interval of 50 hours, the second queue data set is {225, 285}.

In other embodiments, data of a feature value equal to the average interval may be categorized into the second queue data set. In addition, in other embodiments, the data in the second queue data set and the third queue data set may be in descending order of feature values corresponding to the data.

In S106, a distribution sequence of distributing the N batches of wafers to all the radio frequency devices to perform the preset process processing is obtained based on the second queue data set and the third queue data set.

The following two manners may be used to obtain the distribution sequence based on the second queue data set and the third queue data set.

In some embodiments, the step of obtaining a distribution sequence based on the second queue data set and the third queue data set includes the following operations.

According to an arrangement sequence of the data in the second queue data set, a first distribution sequence of distributing the N batches of wafers to radio frequency devices corresponding to the data in the second queue data set is obtained.

For the first distribution sequence, the N batches of wafers are sequentially distributed to radio frequency devices corresponding to the data in the second queue data set according to an arrangement sequence of the data in the second queue data set.

If the radio frequency devices in the second queue data set all correspond to a batch of wafers, a second distribution sequence of distributing the remaining batches of wafers to radio frequency devices corresponding to the data in the third queue data set is obtained according to an arrangement sequence of the data in the third queue data set.

For the second distribution sequence, the remaining batches of wafers are sequentially distributed to radio frequency devices corresponding to the data in the third queue data set according to an arrangement sequence of the data in the third queue data set.

It needs to be noted that if the remaining batches of wafers only correspond to a part of data in the third queue data set, radio frequency devices with actual working durations close to the optimal working durations are selected from radio frequency devices corresponding to the remaining data that does not correspond to wafers, and the selected radio frequency devices are maintained, which helps to prevent all actual operating durations of a plurality of radio frequency devices from reaching upper limits at the same time, to implement maintenance of the plurality of radio frequency devices in batches. In this way, it is ensured that during processing of wafers, some radio frequency devices with relatively short actual working durations can participate in work, to avoid serious instantaneous loss of production capacity, which helps to improve the stability of the production capacity of a semiconductor device in an overall manufacturing procedure of semiconductor structures.

It needs to be noted that under the premise of obtaining the distribution sequence in the foregoing embodiments, before the obtaining a distribution sequence, the method for controlling a distribution sequence for a semiconductor device may further include: obtaining running status of the chambers corresponding to the data, and keeping data corresponding to chambers with the running status being runnable.

The running status of a chamber is affected by many factors, for example, status of parts in the chamber, status of pipes in the chamber, and running status of radio frequency devices in the chamber. When the running status of the chamber is runnable, it represents that the chamber can process a wafer to manufacture semiconductor structures. In addition, the running status of the chambers is examined before the distribution sequence is obtained, so that a chamber that does not satisfy a manufacturing requirement is excluded in advance, to reduce a probability that the production capacity decreases because the running status of a chamber corresponding to a wafer is not runnable, thereby further improving the stability of the production capacity of a semiconductor device.

In addition, in an embodiment, the step of obtaining running status of the chambers corresponding to the data and keeping data corresponding to chambers with the running status being runnable may be performed before the distribution sequence is obtained or may be further performed before the first queue data set is formed. In this way, a processing amount of data when the steps of obtaining a difference and forming the second queue data set and the third queue data set subsequently is reduced, thereby improving the efficiency of controlling a distribution sequence for a semiconductor device. In addition, in another embodiment, the step of obtaining running status of the chambers corresponding to the data and keeping data corresponding to chambers with the running status being runnable may be performed after the second queue data set is obtained and before the distribution sequence is obtained.

It needs to be noted that the step of obtaining running status of the chambers corresponding to the data and keeping data corresponding to chambers with the running status being runnable may be performed in any step before the distribution sequence is obtained, so that a chamber that does not satisfy a manufacturing requirement is excluded in advance, to reduce a probability that the production capacity decreases because the running status of a chamber corresponding to a wafer is not runnable, thereby further improving the stability of the production capacity of a semiconductor device.

In some other embodiments, referring to FIG. 2, the step of obtaining a distribution sequence based on the second queue data set and the third queue data set includes the following operations.

In S116, first tags are sequentially attached to chambers corresponding to the data in the second queue data set, and second tags are sequentially attached to chambers corresponding to the data in the third queue data set, where the first tags and the second tags follow an ascending pattern, and the first tags are greater than the second tags.

When the first tags are greater than the second tags, it represents that any first tag is greater than any second tag. The “greater” means that when wafers need to be processed subsequently, chambers with the first tags are preferentially used for processing.

In an embodiment, the first tags may include C11, C12, C13, C14, . . . , C120, C121, C122, . . . . It may be understood that the first tags may include C1#. # is a positive integer that sequentially increments from 1. C11 denotes a chamber corresponding to the first piece of data in the second queue data set. C1# denotes a chamber corresponding to a #^{th} piece of data in the second queue data set. The second tags may include C21, C22, C23, C24, . . . , C220, C221, C222, . . . . It may be understood that the second tags may include C2#. # is a positive integer that sequentially increments from 1. C21 denotes a chamber corresponding to the first piece of data in the third queue data set. C2# denotes a chamber corresponding to a #^{th} piece of data in the third queue data set.

It needs to be noted that in some embodiments, before the attaching first tags or second tags to chambers, the method for controlling a distribution sequence for a semiconductor device may further include: obtaining running status of all the chambers corresponding to the data, and keeping data corresponding to chambers with the running status being runnable. In this way, a chamber that does not satisfy a manufacturing requirement is excluded in advance, to reduce a probability that the production capacity decreases because the running status of a chamber corresponding to a wafer is not runnable, thereby further improving the stability of the production capacity of a semiconductor device.

In addition, in an embodiment, the step of obtaining running status of the chambers corresponding to the data and keeping data corresponding to chambers with the running status being runnable may be performed before the first tags or second tags are attached to the chambers or may be further performed before the first queue data set is formed. In this way, a processing amount of data when the steps of obtaining a difference and forming the second queue data set and the third queue data set subsequently is reduced, thereby improving the efficiency of controlling a distribution sequence for a semiconductor device. In addition, in another embodiment, the step of obtaining running status of the chambers corresponding to the data and keeping data corresponding to chambers with the running status being runnable may be performed after the second queue data set is obtained and before the first tags or second tags are attached to the chambers.

It needs to be noted that the step of obtaining running status of the chambers corresponding to the data and keeping data corresponding to chambers with the running status being runnable may be performed in any step before the distribution sequence, so that a chamber that does not satisfy a manufacturing requirement is excluded in advance, to reduce a probability that the production capacity decreases because the running status of a chamber corresponding to a wafer is not runnable, thereby further improving the stability of the production capacity of a semiconductor device.

In S126, identifiers of the machines are obtained based on the first tags and the second tags, where the smallest first tag in each machine is used as an identifier of the machine, and if the machine does not have the first tags, the smallest second tag in each machine is used as an identifier of the machine.

For some machines, one machine may include a plurality of chambers and radio frequency devices that correspond one to one to the plurality of chambers. Therefore, one machine may include a plurality of first tags and/or a plurality of second tags. Therefore, the identifiers of the machines are obtained based on the first tags and the second tags, to facilitate sorting of the machines, to subsequently determine a sequence in which N batches of wafers are processed by a plurality of machines.

In an embodiment, the semiconductor device includes a first machine, a second machine, and a third machine. The first machine includes five chambers with tags of C141, C23, C14, C11, and C25, and running status of the chamber with the tag of C11 is not runnable. The second machine includes five chambers with tags of C12, C17, C21, C29, and C210, and running status of the chamber with the tag of C21 is not runnable. The third machine includes five chambers with tags of C13, C15, C28, C16, and C215, and running status of two chambers with the tags of C13 and C215 is not runnable. In this case, an identifier of the first machine is C14, an identifier of the second machine is C12, and an identifier of the third machine is C15.

In S136, the machines are sorted in ascending order of the identifiers.

In an embodiment, if the identifier of the first machine is C14, the identifier of the second machine is C12, and the identifier of the third machine is C15, an arrangement sequence of the three machines is the second machine, the first machine, and the third machine.

In S146, the distribution sequence is obtained according to an arrangement sequence of the machines, and in a single machine, a third distribution sequence of distributing M batches of wafers to all radio frequency devices in the single machine is obtained in an ascending order of the first tags and the second tags, where M and N are both positive integers greater than 1, and M is less than N. In this way, a probability that chambers with relatively short actual working durations are preferentially used for wafer processing is increased, to intelligently control which radio frequency devices are to participate in work, to avoid causing serious instantaneous loss of production capacity and improve the stability of the production capacity of a semiconductor device.

In an embodiment, the identifier of the first machine is C14, the identifier of the second machine is C12, and the identifier of the third machine is C15. That is, the arrangement sequence of the three machines is the second machine, the first machine, and the third machine. The N batches of wafers are sequentially distributed to the second machine, the first machine, and the third machine. In addition, in the second machine, four batches of wafers are sequentially distributed to radio frequency devices corresponding to C12, C17, C29, and C210 in a sequence of C12, C17, C29, and C210. In the first machine, four batches of wafers are sequentially distributed to radio frequency devices corresponding to C14, C141, C23, and C25 in a sequence of C14, C141, C23, and C25. In the third machine, three batches of wafers are sequentially distributed to radio frequency devices corresponding to C15, C16, and C28 in a sequence of C15, C16, and C28.

It needs to be noted that in some embodiments, the machines have a plurality of ports, the ports are used for transporting a batch of wafers into chambers corresponding to the ports, chambers with the first tags are first chambers, and chambers with the second tags are second chambers.

Based on this, the obtaining the distribution sequence according to an arrangement sequence of the machines may include the following steps:

Status of the ports is obtained, and the quantity of ports with status being runnable in each machine is obtained.

In an embodiment, the semiconductor device includes a first machine, a second machine, and a third machine. The first machine includes five chambers with tags of C141, C23, C14, C11, and C25, and running status of the chamber with the tag of C11 is not runnable. The second machine includes five chambers with tags of C12, C17, C21, C29, and C210, and running status of the chamber with the tag of C21 is not runnable. The third machine includes five chambers with tags of C13, C15, C28, C16, and C215, and running status of two chambers with the tags of C13 and C215 is not runnable. In addition, the first machine includes four runnable ports, the second machine includes two runnable ports, and the third machine includes three runnable ports.

If one machine includes both the first chambers and the second chambers and has the quantity of ports being an even number, it is set that the quantity of ports corresponding to the first chambers is equal to the quantity of ports corresponding to the second chambers. For example, the first machine includes two first chambers C141 and C14 and further includes two second chambers C23 and C25. In this case, it is set that the quantity of ports corresponding to the first chambers is 2, and the quantity of ports corresponding to the second chambers is 2.

If one machine includes both the first chambers and the second chambers and has the quantity of ports being an odd number, it is set that the quantity of ports corresponding to the first chambers is greater than the quantity of ports corresponding to the second chambers by 1. For example, the third machine includes two first chambers C15 and C16 and further includes one second chamber C28. In this case, it is set that the quantity of ports corresponding to the first chambers is 2, and the quantity of ports corresponding to the second chambers is 1.

It needs to be noted that a batch of wafers can be transported into a chamber corresponding to a port for wafer processing only when status of the port is runnable.

Based on the embodiments of the disclosure, the quantity of ports with status being runnable in each machine is distributed, so that a port that does not satisfy a manufacturing requirement is excluded in advance, to reduce a probability that the production capacity decreases because the status of a port corresponding to a wafer is not runnable. A probability that chambers with relatively short actual working durations are preferentially used for wafer processing is further increased, to intelligently control which radio frequency devices are to participate in work, to avoid causing serious instantaneous loss of production capacity and improve the stability of the production capacity of a semiconductor device.

In some embodiments, before the quantity of ports corresponding to the first chambers is set and the quantity of ports corresponding to the second chambers is set, the method for controlling a distribution sequence for a semiconductor device may further include the following operations.

The preset total quantity of batches of wafers that need to be processed within a preset time is obtained, and the actual total quantity of batches of wafers allowed to be processed by all the machines within the preset time is obtained.

If the preset total quantity is greater than or equal to the actual total quantity, the quantity of ports corresponding to the first chambers is set, and the quantity of ports corresponding to the second chambers is set. If the preset total quantity is less than the actual total quantity and one machine includes both the first chambers and the second chambers, it is set that the ports in the machines all correspond to the first chambers. A probability that actual working durations of radio frequency devices in the first chambers are relatively short is greater than a probability that actual working durations of radio frequency devices in the second chambers is relatively short. Therefore, if the semiconductor device has been in a non-full load state for years, the N batches of wafers are all processed by the first chambers, so that more radio frequency devices with relatively short actual working durations are used to process wafers, to implement full utilization of the radio frequency devices, thereby improving the quality of eventually manufactured semiconductor structures and the production capacity of the semiconductor device.

It may be understood that if the preset total quantity is less than the actual total quantity and a machine includes only first chambers or second chambers, the N batches of wafers can all be processed by the first chambers or second chambers.

It needs to be noted that when the first tags and second tags are attached to the chambers, the machines are identified and sorted, but neither the running status of the chambers nor the status of the ports is obtained, and the step of obtaining the distribution sequence according to an arrangement sequence of the machines may include: obtaining the preset total quantity of batches of wafers that need to be processed within the preset time, and obtaining the actual total quantity of batches of wafers allowed to be processed by all the machines within the preset time; and if the preset total quantity is less than the actual total quantity and one machine includes both the first chambers and the second chambers, setting that the ports in the machines all correspond to the first chambers. In addition, if the preset total quantity is greater than or equal to the actual total quantity, the chambers corresponding to the data in the second queue data set may be preferentially used for wafer processing, and the remaining batches of wafers are processed by the chambers corresponding to the data in the third queue data set.

In summary, in a second queue data set, there is a relatively high probability that actual working durations of radio frequency devices represented by data are relatively short, that is, the actual working durations of the radio frequency devices in the second queue data set are mostly relatively short, and the radio frequency devices in the second queue data set may be preferentially arranged to perform preset process processing on N batches of wafers, so that excessive radio frequency devices with actual working durations approaching optimal working durations are prevented from participating in work, to avoid affecting the quality of semiconductor structures and reduce the production capacity of a semiconductor device. In addition, when the quantity of batches of wafers that require preset process processing is not large, for example, when the quantity of batches of wafers that require preset process processing is less than the quantity of data included in the second queue data set, radio frequency devices corresponding to data in the third queue data set may be arranged for maintenance, thereby preventing all actual operating durations of a plurality of radio frequency devices from reaching upper limits at the same time, to avoid serious instantaneous loss of production capacity. Therefore, the method for controlling a distribution sequence for a semiconductor device provided in the embodiments of the disclosure helps to intelligently control which radio frequency devices are to participate in work, to avoid causing serious instantaneous loss of production capacity and improve the stability of the production capacity of the semiconductor device.

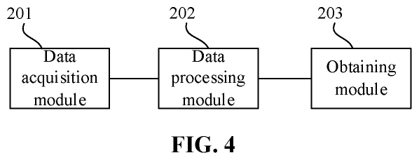

Another embodiment of the disclosure further provides an apparatus for controlling a distribution sequence for a semiconductor device, configured to perform the method for controlling a distribution sequence for a semiconductor device in any foregoing embodiment. The apparatus for controlling a distribution sequence for a semiconductor device provided in some embodiments of the disclosure is described below in detail with reference to the accompanying drawings. FIG. 4 is a schematic diagram of functional modules of an apparatus for controlling a distribution sequence for a semiconductor device according to another embodiment of the disclosure.

Referring to FIG. 4, the apparatus for controlling a distribution sequence for a semiconductor device includes: a data acquisition module 201, configured to acquire the quantity of all chambers in which preset process processing is allowed and data of all the machines, where the data is an actual working duration of each radio frequency device in the machines; a data processing module 202, configured to process the data, the data processing module 202 being configured to: provide optimal working durations of the radio frequency devices, and calculate an average interval according to the optimal working durations and the quantity; sort all the data to form a first queue data set, and obtain a difference between adjacent data in the first queue data set; obtain feature values corresponding to the data in the first queue data set based on the difference, where a difference between adjacent consecutive data is used as a feature value corresponding to the former or latter data in the consecutive data, and data that does not correspond to the difference is used as a feature value corresponding to the data; obtain a second queue data set and a third queue data set based on the average interval and the feature values, where the second queue data set is formed by sorting data corresponding to feature values less than the average interval, and the third queue data set is formed by sorting data corresponding to feature values greater than or equal to the average interval; and an obtaining module 203, configured to obtain, based on the second queue data set and the third queue data set, a distribution sequence of distributing the N batches of wafers to all the radio frequency devices to perform the preset process processing.

The foregoing apparatus obtains the distribution sequence of distributing the N batches of wafers to all the radio frequency devices to perform the preset process processing, so that a probability that radio frequency devices with relatively short actual working durations are preferentially used for wafer processing is increased, and when some radio frequency devices are controlled to perform wafer processing, the remaining radio frequency devices that have not participated in wafer processing may be controlled for maintenance, to implement maintenance of the plurality of radio frequency devices in batches. In this way, it is ensured that during processing of wafers, some radio frequency devices with relatively short actual working durations can participate in work, to intelligently control which radio frequency devices are to participate in work, to avoid causing serious instantaneous loss of production capacity and improve the stability of the production capacity of a semiconductor device.

In some embodiments, the data corresponds one to one to the radio frequency devices, the radio frequency devices correspond one to one to the chambers, and the apparatus for controlling a distribution sequence for a semiconductor device may further include: a tagging unit (not shown in the figure), configured to sequentially attach first tags to chambers corresponding to the data in the second queue data set, sequentially attach second tags to chambers corresponding to the data in the third queue data set, and attach tags to the machines. In this way, machines including most radio frequency devices with relatively short actual working durations are preferentially used for wafer processing, and in one same machine, radio frequency devices in chambers with relatively small first tags are preferentially used, so that a probability that chambers with relatively short actual working durations are preferentially used for wafer processing is further increased.

In some embodiments, the obtaining module is further configured to obtain running status of the chambers, if running status of the chambers is runnable, the chambers can be used for wafer processing. In this way, a chamber that does not satisfy a manufacturing requirement is excluded in advance, to reduce a probability that the production capacity decreases because the running status of a chamber corresponding to a wafer is not runnable, thereby further improving the stability of the production capacity of a semiconductor device. In some other embodiments, the machines have a plurality of ports, and the obtaining module is further configured to obtain running status of the chambers and obtain status of the ports, and if status of ports is runnable, a batch of wafers are transported into a chamber corresponding to the ports for wafer processing. In this way, a port that does not satisfy a manufacturing requirement is excluded in advance, to reduce a probability that the production capacity decreases because the status of a port corresponding to a wafer is not runnable. It needs to be noted that in other embodiments, due to different requirements of actual applications, instead of the running status of the chambers, the obtaining module may obtain the status of ports.

A person of ordinary skill in the art may understand that the foregoing implementations are specific embodiments for implementing the disclosure, and in actual applications, various changes can be made thereto in forms and details without departing from the spirit and scope of the embodiments of the disclosure. Any person skilled in the art can make changes and modifications without departing from the spirit and scope of the embodiments of the disclosure, and the scope of protection of the embodiments of the disclosure should be as defined by the scope of the claims.

What is claimed is:

1. A method for controlling a distribution sequence for a semiconductor device, the semiconductor device comprising a plurality of machines, each machine having at least one chamber and a radio frequency device corresponding one to one to the chamber, wherein the method comprises:
before preset process processing is performed on N batches of wafers, acquiring a quantity of all chambers in which the preset process processing is allowed and data of all the machines, wherein the data is an actual working duration of each radio frequency device in the machines;
providing optimal working durations of the radio frequency devices, and calculating an average interval according to the optimal working durations and the quantity;
sorting all the data to form a first queue data set, and obtaining a difference between adjacent data in the first queue data set;
obtaining feature values corresponding to the data in the first queue data set based on the difference, wherein a difference between adjacent consecutive data is used as a feature value corresponding to the former or latter data in the consecutive data, and data that does not correspond to the difference is used as a feature value corresponding to the data;
obtaining a second queue data set and a third queue data set based on the average interval and the feature values, wherein the second queue data set is formed by sorting data corresponding to feature values less than the average interval, and the third queue data set is formed by sorting data corresponding to feature values greater than or equal to the average interval; and
obtaining, based on the second queue data set and the third queue data set, a distribution sequence of distributing the N batches of wafers to all the radio frequency devices to perform the preset process processing.

2. The method according to claim 1, wherein the forming the second queue data set and the third queue data set through sorting comprises:
sorting the data of the feature values less than the average interval in ascending order of the feature values to form the second queue data set; and
sorting the data of the feature values greater than or equal to the average interval in ascending order of the feature values to form the third queue data set.

3. The method according to claim 1, wherein the obtaining a distribution sequence based on the second queue data set and the third queue data set comprises:
obtaining, according to an arrangement sequence of the data in the second queue data set, a first distribution sequence of distributing the N batches of wafers to radio frequency devices corresponding to the data in the second queue data set; and
in a case where the radio frequency devices in the second queue data set all correspond to a batch of wafers, obtaining, according to an arrangement sequence of the data in the third queue data set, a second distribution sequence of distributing the remaining batches of wafers to radio frequency devices corresponding to the data in the third queue data set.

4. The method according to claim 3, wherein the data corresponds one to one to the radio frequency devices, the radio frequency devices correspond one to one to the chambers, and before the obtaining a distribution sequence, the method further comprises: obtaining running status of the chambers corresponding to the data, and keeping data corresponding to chambers with the running status being runnable.

5. The method according to claim 4, wherein before the first queue data set is formed, the running status is obtained, and the data corresponding to the chambers with the running status being runnable is kept; or after the second queue data set is obtained, the running status is obtained, and the data corresponding to the chambers with the running status being runnable is kept.

6. The method according to claim 1, wherein the data corresponds one to one to the radio frequency devices, the radio frequency devices correspond one to one to the chambers, and the step of obtaining a distribution sequence based on the second queue data set and the third queue data set comprises:
sequentially attaching first tags to chambers corresponding to the data in the second queue data set, and sequentially attaching second tags to chambers corresponding to the data in the third queue data set, wherein the first tags and the second tags follow an ascending pattern, and the first tags are greater than the second tags;
obtaining identifiers of the machines based on the first tags and the second tags, wherein the smallest first tag in each machine is used as an identifier of the machine, and in a case where the machine does not have the first tags, the smallest second tag in each machine is used as an identifier of the machine;
sorting the machines in ascending order of the identifiers; and
obtaining the distribution sequence according to an arrangement sequence of the machines, and in a single machine, obtaining, in an ascending order of the first tags and the second tags, a third distribution sequence of distributing M batches of wafers to all radio frequency devices in the single machine, wherein M and N are both positive integers greater than 1, and M is less than N.

7. The method according to claim 6, wherein before the attaching first tags or second tags to chambers, the method further comprises: obtaining running status of all the chambers corresponding to the data, and keeping data corresponding to chambers with the running status being runnable.

8. The method according to claim 7, wherein before the first queue data set is formed, the running status is obtained, and the data corresponding to the chambers with the running status being runnable is kept; or after the second queue data set is obtained, the running status is obtained, and the data corresponding to the chambers with the running status being runnable is kept.

9. The method according to claim 6, wherein the machines have a plurality of ports, the ports are used for transporting a batch of wafers into chambers corresponding to the ports, chambers with the first tags are first chambers, chambers with the second tags are second chambers, and the step of obtaining the distribution sequence according to an arrangement sequence of the machines comprises:
obtaining status of the ports, and obtaining a quantity of ports with status being runnable in each machine;
in a case where one machine comprises both the first chambers and the second chambers and has a quantity of ports being an even number, setting that a quantity of ports corresponding to the first chambers is equal to a quantity of ports corresponding to the second chambers; and
in a case where one machine comprises both the first chambers and the second chambers and has a quantity of ports being an odd number, setting that a quantity of ports corresponding to the first chambers is greater than a quantity of ports corresponding to the second chambers by 1.

10. The method according to claim 9, wherein before the quantity of ports corresponding to the first chambers is set and the quantity of ports corresponding to the second chambers is set, the method further comprises:
obtaining a preset total quantity of batches of wafers that need to be processed within a preset time, and obtaining an actual total quantity of batches of wafers allowed to be processed by all the machines within the preset time; and
in a case where the preset total quantity is greater than or equal to the actual total quantity, setting the quantity of ports corresponding to the first chambers, and setting the quantity of ports corresponding to the second chambers.

11. The method according to claim 6, wherein the machines have a plurality of ports, the ports are used for transporting a batch of wafers into chambers corresponding to the ports, chambers with the first tags are first chambers, chambers with the second tags are second chambers, and the step of obtaining the distribution sequence according to an arrangement sequence of the machines comprises:
obtaining the preset total quantity of batches of wafers that need to be processed within the preset time, and obtaining the actual total quantity of batches of wafers allowed to be processed by all the machines within the preset time; and
in a case where the preset total quantity is less than the actual total quantity and one machine comprises both the first chambers and the second chambers, setting that the ports in the machines all correspond to the first chambers.

12. The method according to claim 1, wherein the sorting all the data and obtaining a feature value corresponding to the data in the first queue data set based on the difference comprises:
sorting all the data in ascending order; and
using the difference between adjacent consecutive data as a feature value corresponding to the latter data in the consecutive data, and using first data as a feature value corresponding to the first data.

13. The method according to claim 1, wherein the sorting all the data and obtaining a feature value corresponding to the data in the first queue data set based on the difference comprises:
sorting all the data in descending order; and
using the difference between adjacent consecutive data as a feature value corresponding to the former data in the consecutive data, and using last data as a feature value corresponding to the last data.

14. An apparatus for controlling a distribution sequence for a semiconductor device, wherein the semiconductor device comprising a plurality of machines, each machine having at least one chamber and a radio frequency device corresponding one to one to the chamber, wherein the apparatus comprises:
a processor; and
a memory storing instructions executable by the processor, wherein when executing the instructions stored in the memory, the processor is configured to:
before preset process processing is performed on N batches of wafers, acquire a quantity of all chambers in which the preset process processing is allowed and data of all the machines, wherein the data is an actual working duration of each radio frequency device in the machines;
provide optimal working durations of the radio frequency devices, and calculate an average interval according to the optimal working durations and the quantity;
sort all the data to form a first queue data set, and obtain a difference between adjacent data in the first queue data set;
obtain feature values corresponding to the data in the first queue data set based on the difference, wherein a difference between adjacent consecutive data is used as a feature value corresponding to the former or latter data in the consecutive data, and data that does not correspond to the difference is used as a feature value corresponding to the data;
obtain a second queue data set and a third queue data set based on the average interval and the feature values, wherein the second queue data set is formed by sorting data corresponding to feature values less than the average interval, and the third queue data set is formed by sorting data corresponding to feature values greater than or equal to the average interval; and
obtain, based on the second queue data set and the third queue data set, a distribution sequence of distributing the N batches of wafers to all the radio frequency devices to perform the preset process processing.

15. The apparatus according to claim 14, wherein the data corresponds one to one to the radio frequency devices, the radio frequency devices correspond one to one to the chambers, and the processor is further configured to: sequentially attach first tags to chambers corresponding to the data in the second queue data set, sequentially attach second tags to chambers corresponding to the data in the third queue data set, and attach tags to the machines.

16. The apparatus according to claim 14, wherein the machines have a plurality of ports, and the processor is further configured to obtain at least one of running status of the chambers or status of the ports.

17. A non-transitory computer-readable storage medium, having computer program stored thereon, wherein when executed by an electronic device, the computer program causes a processor in the electronic device to implement the method according to claim 1.
